(19) United States
(12) Patent Application Publication
(10) Pub. No.: US 2019/0071599 A1
(43) Pub. Date: Mar. 7, 2019

(54) LIGHT EMITTING NANOPARTICLES AND PROCESS OF MAKING THE SAME

(71) Applicants: Dow Global Technologies LLC, Midland, MI (US); Rohm and Haas Electronic Materials LLC, Marlborough, MA (US)

(72) Inventors: Xiuyan Wang, Shanghai (CN); Bo Lu, Shanghai (CN); Yang Li, Shanghai (CN); Nan Hu, Shanghai (CN); Xiaofan Ren, Beijing (CN); Peter Trefonas, III, Medway, MA (US); Yuanqiao Rao, Berwyn, PA (US)

(73) Assignees: Dow Global Technologies LLC, Midland, MI (US); Rohm and Haas Electronic Materials LLC, Marlborough, MA (US); Rohm and Haas Electronic Materials LLC, Marlborough, MA (US)

(21) Appl. No.: 15/774,289

(22) PCT Filed: Nov. 11, 2015
(86) PCT No.: PCT/CN2015/094262

§ 371 Date: May 8, 2018

(51) Int. Cl. C09K 11/07; C09K 11/02; H01L 51/00

(52) U.S. Cl. CPC C09K 11/07; B82Y 10/00; H01L 51/0094; C09K 11/02

(57) ABSTRACT

Light emitting nanoparticles have improved photostability, thermal stability and emission properties, and a process of preparing the nanoparticles.

### FIELD OF THE INVENTION

The present invention relates to light emitting nanoparticles and a process of making the same.

### INTRODUCTION

After half a century of extensive material research and device development, thin film transistor liquid crystal display (TFT-LCD) has become the dominant flat panel display technology. While many critical issues, such as viewing angle, contrast ratio and power consumption, have been resolved to an acceptable level, liquid crystal display (LCD) still has room for improvement at color gamut. Recently, Quantum Dot (QD) based LCD is emerging as a new backlight source. As photo-emitters, quantum dots have many advantages, such as high emission intensity, broad and strong absorption and narrow emission bands; however, significant challenges remain in terms of cost reduction, mass production and compatibility with current LCD backlight assembling process. In addition, QDs are sensitive to oxygen and moisture, which demands the use of encapsulation films when incorporating QDs to the LCD backlight.

Therefore, it is desirable to provide novel emitting species that offer similar electro-optical properties as quantum dots but can potentially be cheaper and easier for mass production, and also eliminate the use of encapsulation films.

### SUMMARY OF THE INVENTION

The present invention provides novel light emitting nanoparticles. The nanoparticles may have a core covalently bonded with a luminophore and a hybrid shell at least partially encapsulating the core. The nanoparticles of the present invention provide improved photostability, thermal stability and emission properties than light emitting materials that the luminophore derives from.

In a first aspect, the present invention provides nanoparticles prepared by a process comprising:

(i) providing a functionalized light emitting compound, wherein the functionalized light emitting compound has the structure of D-L-SiX₃, wherein D is a luminophore, L is a direct bond or an organic group, and X is a hydrolyzable substituent;

(ii) pre-hydrolyzing the functionalized light emitting compound;

(iii) adding a first precursor, wherein the first precursor is selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and

(iv) adding a second precursor, wherein the second precursor comprises (a) a second organic silane compound having the structure of SiX²₄, and (b) a second organic metal compound having the structure of MX²₃ or MX²₄; wherein each X² is independently a hydrolyzable substituent, and M is selected from Al, Zr, Ti, or combinations thereof; thus to obtain the nanoparticles.

In a second aspect, the present invention provides nanoparticles having a particle size in the range of from 10 to 2,000 nm, wherein the nanoparticles comprise:

a core comprising a reaction product of a functionalized light emitting compound and a first precursor, wherein the functionalized light emitting compound has the structure of D-L-SiX₃, wherein D is a luminophore, L is a direct bond or an organic group, and X is a hydrolyzable substituent; and the first precursor is selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and

a shell comprising a reaction product of a second precursor, wherein the second precursor comprises (a) a second organic silane compound having the structure of SiX²₄, and (b) a second organic metal compound having the structure of MX²₃ or MX²₄; wherein each X² is independently a hydrolyzable substituent, and M is selected from Al, Zr, Ti, or combinations thereof; and the molar ratio of the second organic silane compound to the second organic metal compound is from 1:1 to 50:1.

In a third aspect, the present invention provides a process of preparing the nanoparticles of the first or second aspect. The process comprises:

(i) providing a functionalized light emitting compound, wherein the functionalized light emitting compound has the structure of D-L-SiX₃, wherein D is a luminophore, L is a direct bond or an organic group, and X is a hydrolyzable substituent;

(ii) pre-hydrolyzing the functionalized light emitting compound;

(iii) adding a first precursor selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and

(iv) adding a second precursor, wherein the second precursor comprises (a) a second organic silane compound having the structure of SiX²₄ and (b) a second organic metal compound having the structure of MX²₃ or MX²₄, wherein each X² is a hydrolyzable substituent, and M is selected from Al, Zr, Ti, or combinations thereof; thus to obtain the nanoparticles.

In a fourth aspect, the present invention provides a light emitting composition comprising one or more than one types of the nanoparticles of the first or second aspect, and an additional light emitting material that is different from the nanoparticles.

In a fifth aspect, the present invention provides an electronic device comprising a layer of the nanoparticles of the first or second aspect.

### BRIEF DESCRIPTION OF THE DRAWINGS

FIG. 1 is Scanning Transmission Electron Microscopy (STEM) images of (a) Example 2, (b) Example 3, (c) Comparative Example B, and (d) Comparative Example C.

FIG. 2 is an emission spectrum of nanoparticles of Example 3.

### DETAILED DESCRIPTION OF THE INVENTION

A “luminophore” refers to an atom or functional group in a chemical compound that is responsible for its luminescent properties when exposed to electromagnetic radiation. Luminophore may be referred to herein as light-emitting groups and vice-versa.

An “electronic device” refers to a device which depends on the principles of electronics and uses the manipulation of electron flow for its operation.

An “alkyl” refers to an acyclic saturated monovalent hydrocarbon group and includes linear and branched groups with hydrogen unsubstituted or substituted by a halogen, a hydroxyl, a cyano, a sulfo, a nitro, an alkyl, a perfluoroalkyl, or combinations thereof.

A “heteroalkyl” refers to a saturated hydrocarbon group having a linear or branched structure wherein one or more of the carbon atoms within the alkyl group has been replaced with a heteroatom or a heterofunctional group containing at least one heteroatom. Heteroatoms may include, for example, O, N, P, S and the like. The heterofunctional group containing at least one heteroatom herein may include, for example, COOR′, OCOOR′, OR′, NR′₂, PR′₂, P(═O)R′₂, or SiR′₃; where each R′ is H, an unsubstituted or substituted C₁-C₃₀ hydrocarbyl group, or an unsubstituted or substituted C₆-C₃₀ aromatic group.

An “alkenyl” refers an unsaturated hydrocarbon that contains at least one carbon-carbon double bond. A substituted alkenyl refers to an alkenyl wherein at least one of the hydrogens on the carbon double bond is replaced by an atom or group other than H, for example, a C₁-C₃₀ alkyl group or C₆-C₃₀ aromatic group. An “alkynyl” refers to an unsaturated hydrocarbon containing at least one carbon-carbon triple bond. A substituted alkenyl refers to an alkenyl wherein at least one of the hydrogens on the carbon double bond is replaced by an atom or group other than H, for example, a C₁-C₃₀ alkyl group or C₆-C₃₀ aromatic group. In case that an alkenyl or alkynyl group contains more than one unsaturated bonds, these bonds usually are not cumulated, but may be arranged in an alternating order, such as in —[CH═CH—]ₚ, where p may be in the range of 2-50. Where not defined otherwise, preferred alkyl contains 1-22 carbon atoms; preferred alkenyl and alkynyl contain 2-22 carbon atoms.

An “alkoxy” refers to an alkyl group singular bonded with oxygen. Alkoxy such as C₁-C₂₄ alkoxy is a straight-chain or branched radical, for example, methoxy, ethoxy, isopropoxy, n-butoxy, sec-butoxy, tert-butoxy, heptyloxy, octyloxy, isooctyloxy, nonyloxy, decyloxy, undecyloxy, dodecyloxy, tetradecyloxy, hexadecyloxy, and octadecyloxy. A substituted alkoxy refers to a substituted alkyl group singular bonded with oxygen.

An “aliphatic cyclic group” refers to an organic group that is both aliphatic and cyclic. The aliphatic cyclic group contains one or more carbon rings that can be either saturated or unsaturated. A substituted aliphatic cyclic group may have one or more side chains attached where the side chain can be a substituted or unsubstituted alkyl, a substituted or unsubstituted heteroalkyl, a substituted or unsubstituted alkenyl, a substituted or unsubstituted alkynyl, or a substituted or unsubstituted alkoxy. Examples of aliphatic cyclic groups include cyclobutyl, cyclopentyl, cyclohexyl, methylcyclohexyl, dimethylcyclohexyl, trimethylcyclohexyl, 1-adamantyl, and 2-adamantyl.

A “heterocyclic group” refers to a cyclic compound that has atoms of at least two different elements as members of its ring(s). A heterocyclic group usually contains 5 to 7 ring members, among them, at least 1, especially 1-3, heteromoieties, usually selected from O, S, NR′. Examples include C₄-C₁₈ cycloalkyl, which is interrupted by 0, S, or NR′, such as piperidyl, tetrahydrofuranyl, piperazinyl, and morpholinyl. Unsaturated variants may be derived from these structures, by abstraction of a hydrogen atom on adjacent ring members with formation of a double bond between them; an example for such a moiety is cyclohexenyl. A substituted heterocyclic group may have one or more side chains attached, where the side chain can be substituted or unsubstituted alkyl, substituted or unsubstituted heteroalkyl, substituted or unsubstituted alkenyl, substituted or unsubstituted alkynyl, substituted or unsubstituted alkoxy, or another heterocyclic group either directed linked together or via linking groups.

An “aromatic group” refers to a hydrocarbon with sigma bonds and delocalized pi electrons between carbon atoms forming rings, usually the benzene-based, or aryl groups. Aryl is defined as an aromatic or polyaromatic substituent containing 1 to 4 aromatic rings (each ring containing 6 conjugated carbon atoms and no heteroatoms) that are optionally fused to each other or bonded to each other by carbon-carbon single bonds. A substituted aromatic or aryl group refers to an aryl ring with one or more substituents replacing the hydrogen atoms on the ring. The aryl group is unsubstituted or optionally and independently substituted by any synthetically accessible and chemically stable combination of substituents that are independently a halogen, a cyano, a sulfo, a carboxy, an alkyl, a perfluoroalkyl, an alkoxy, an alkylthio, an amino, a monoalkylamino, or a dialkylamino. Examples include substituted or unsubstituted derivatives of phenyl; biphenyl; o-, m-, or p-terphenyl; 1-naphthal; 2-naphthal; 1-, 2-, or 9-anthryl; 1-, 2-, 3-, 4-, or 9-phenanthrenyl and 1-, 2-, or 4-pyrenyl. Preferable aromatic or aryl groups are phenyl, substituted phenyl, naphthyl or substituted naphthyl.

A “heteroaromatic group”, or a “heteroaryl group” refers to a 5- or 6-membered heteroaromatic ring that is optionally fused to an additional 6-membered aromatic ring(s), or is optionally fused to a 5- or 6-membered heteroaromatic rings. The heteroaromatic rings contain at least 1 and as many as 3 heteroatoms that are selected from the group consisting of 0, S or N in any combination. A substituted heteroaromatic or heteroaryl group refers to a heteroaromatic or heteroaryl ring with one or more substituents replacing the hydrogen atoms on the ring. The heteroaromatic or heteroaryl group is unsubstituted or optionally and independently substituted by any synthetically accessible and chemically stable combination of substituents that are independently a halogen, a cyano, a sulfo, a carboxy, an alkyl, a perfluoroalkyl, an alkoxy, an alkylthio, an amino, a monoalkylamino, or a dialkylamino. Examples include substituted or unsubstituted derivatives of 2- or 3-furanyl; 2- or 3-thienyl; N-, 2- or 3-pyrroyl; 2- or 3-benzofuranyl; 2- or 3-benzothienyl; N-, 2-, or 3-indolyl; 2-, 3-, or 4-pyridyl; 2-, 3-, or 4-quinolyl; 1-, 3-, or 4-isoquinlyl; 2-benzoxazolyl; 2-, 4-, or 5-(1,3-oxazolyl); 2-, 4-, or 5-(1,3-thiazolyl); 2-benzothiazolyl; 3-, 4-, or 5-isoxazolyl; N-, 2-, or 4-imidazolyl; N-, or 2-benimidazolyl; 1-, or 2-naphthofuranyl; 1-, or 2-naphthothieyl; N-, 2- or 3-benzindolyl; or 2-, 3-, or 4-benzoquinolyl.

The “quantum yield” of a luminophore is the ratio of the number of emitted photons to the number of photons absorbed.

An “excited state” is an electronic state of a molecule in which the electrons populate an energy state that is higher than another energy state for the molecule.

The functionalized light emitting compound useful in the present invention may have the structure of formula (I):

D-L-SiX₃ (I)

wherein D is a luminophore, L is a direct bond or an organic group, and X is a hydrolyzable substituent. A mixture of two or more types of the functionalized light emitting compounds may be used.

L in formula (I) can comprise a divalent, a trivalent, a tetravalent or a pentavalent moiety. For example, L can be an unsubstituted or substituted alkyl, such as a C₁-C₁₂, C₁-C₈, or C₁-C₄ unsubstituted or substituted alkyl; an unsubstituted or substituted alkoxy, such as a C₁-C₁₂, C₁-C₈, or C₁-C₄ unsubstituted or substituted alkoxy; an unsubstituted or substituted alkenyl group, such as a C₂-C₁₂, C₂-C₈, or C₂-C₄ unsubstituted or substituted alkenyl group; an unsubstituted or substituted alkynyl group, such as a C₂-C₁₂, C₂-C₈, or C₂-C₄ unsubstituted or substituted alkynyl group; an unsubstituted or substituted aliphatic cyclic group, such as a C₃-C₂₀, C₅-C10, or C₅-C₆ unsubstituted or substituted aliphatic cyclic group; an unsubstituted or substituted heterocyclic group, such as a C₃-C₂₀, C₅-C₁₀, or C₅-C₆ unsubstituted or substituted heterocyclic group; an unsubstituted or substituted aromatic group, such as a C₆-C₂₀, C₆-C₁₄, or C₆-C10 unsubstituted or substituted aromatic group; an unsubstituted or substituted heteroaromatic group, such as a C₅-C₂₀, C₅-C₁₄, or C₅-C₆ unsubstituted or substituted heteroaromatic group; an ether, an ester, a urethane, a sulfide, an amide, or an amine. Preferably, L is selected from a C₁-C₈ unsubstituted or substituted alkyl or a C₁-C₁₀ unsubstituted or substituted alkoxy.

X in formula (I) is a hydrolyzable substituent. “Hydrolyzable substituent” in the present invention refers to a functional group which undergoes breakage of chemical bond by the addition of water, optionally in the presence of a catalyst. Examples of suitable X include a C₁-C₁₈ unsubstituted or substituted alkoxy, and preferably a C₁-C₄ unsubstituted or substituted alkoxy. More preferably, X is selected from a methoxy, ethoxy or 2-methoxy-ethoxy. X can also be a —OH group.

D in formula (I) refers to a group derived from a light emitting compound, or a luminophore. A luminophore can be either organic or inorganic. In the present invention, it is preferred that the luminophore is an organic group. A luminophore can be further classified as a fluorophore or a phosphor, depending on the nature of the excited state responsible for the emission of photons. On the other hand, some luminophores can't be classified as exclusively fluorophore or a phosphor. Examples include transition metal complexes, such as tris(2-phenylpyridinyl) iridium. Most fluorophores consists of conjugated pi systems. A typical luminophore is an aromatic or heteroaromatic compound such as a pyrene, an anthracene, an acridine, a stilbene, an indole or benzoindole, a porphyrin, a perylene, a cyanine, a coumarin, naphthalimide, rhodamine, fluoresceine, xanthenes, benzoxanthene, diketopyrrolopyrrole, and the like. Preferably, the light emitting compound which D derives from exhibits a full width half maximum (FWHM) of the emission band of less than 100 nanometers (nm), less than 90 nm, less than 70 nm, or even less than 50 nm. Also preferably, the light emitting compound may have an absorption of at least 1000 M⁻¹ cm⁻¹ in a spectral region of 430-490 nm.

The light emitting compound which D derives from useful in the present invention may have the structure of formula (II):

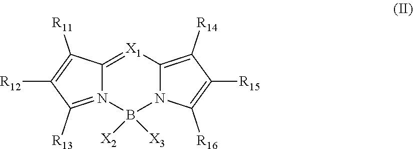

wherein R₁₁ through R₁₆ are each independently selected from H, a halogen, —CN, —CF₃, —NO₂, a C₁-C₂₄ unsubstituted or substituted alkyl, a C₂-C₂₄ unsubstituted or substituted alkenyl, a C₂-C₂₄ unsubstituted or substituted alkynyl, a C₁-C₂₄ unsubstituted or substituted alkoxy, a C₃-C₂₀ unsubstituted or substituted cyclic or heterocyclic group, —SO₃H, sulfonate, —SO₂O—, a thio ether, an ether, a urea, —CO₂H, an ester, an amide, an amine, a C₆-C₂₀ unsubstituted or substituted aromatic group, or a C₅-C₂₀ unsubstituted or substituted heteroaromatic group; R₁₁ and R₁₂ may join together to form a 5-, 6-, 7-membered ring together with the atoms they are bonded; R₁₂ and R₁₃ may join together to form a 5-, 6-, 7-membered ring together with the atoms they are bonded; R₁₄ and R₁₅ may join together to form a 5-, 6-, 7-membered ring together with the atoms they are bonded; and R₁₅ and R₁₆ may join together to form a 5-, 6-, 7-membered ring together with the atoms they are bonded, that may be unsubstituted or substituted;

wherein X₁ is N or CR₁₇, wherein R₁₇ is selected from H, a halogen, —CN, —CF₃, a C₁-C₂₄ unsubstituted or substituted alkyl, a C₂-C₂₄ unsubstituted or substituted alkenyl, a C₂-C₂₄ unsubstituted or substituted alkynyl, a C₁-C₂₄ unsubstituted or substituted alkoxy, a C₃-C₂₀ unsubstituted or substituted cyclic or heterocyclic group, a C₆-C₂₀ unsubstituted or substituted aromatic group, a C₅-C₂₀ unsubstituted or substituted heteroaromatic group, an ether, an ester, a carboxylic acid, —OH, an amide, an amine, or a sulfide; and

wherein X₂ and X₃ are each independently selected from a halogen, a C₁-C₂₄ unsubstituted or substituted alkyl, a C₂-C₂₄ unsubstituted or substituted alkenyl, a C₂-C₂₄ unsubstituted or substituted alkyne, a C₃-C₂₀ unsubstituted or substituted cyclic or heterocyclic group, a C₆-C₂₀ unsubstituted or substituted aromatic group, a C₅-C₂₀ unsubstituted or substituted heteroaromatic group, or a C₁-C₂₄ unsubstituted or substituted alkoxy; and X₂ and X₃ may join together to form a single substituent group.

The C₁-C₂₄ unsubstituted or substituted alkyl in formula (II) may include a C₁-C₂₂, C₁-C₁₆, C₁-C₁₂, or C₁-05 unsubstituted or substituted alkyl. Examples of alkyls include methyl, ethyl, propyl, iso-propyl, butyl, iso-butyl, tert-butyl pentyl, hexyl, heptyl, octyl, or combinations thereof.

The C₂-C₂₄ unsubstituted or substituted alkenyl in formula (II) may include a C₂-C₂₂, C₂-C₁₆, C₂-C₁₂, or C₂-05 unsubstituted or substituted alkenyl. Examples of substituted or unsubstituted alkenyls include ethylene; n-propylene; i-propylene; n-, i-, sec, tert-butylene; n-pentylene; n-hexylene; n-heptylene; n-octylene; or combinations thereof.

The C₂-C₂₄ unsubstituted or substituted alkynyl in formula (II) may include a C₂-C₂₀, C₂-C₁₆, C₂-C₅, or C₂-C₃ unsubstituted or substituted alkynyl. Examples of unsubstituted or substituted alkynyl include ethynyl, propynyl, phenylethylnyl, or combinations thereof.

The C₁-C₂₄ unsubstituted or substituted alkoxy in formula (II) may include a C₁-C₂₀, C₁-C₁₆, C₁-C₁₂, or C₁-05 unsubstituted or substituted alkoxy. Examples of unsubstituted or substituted alkoxys include methoxy; ethoxy; n-, i-propoxy; n-, i-, sec-, tert-butoxy; n-penyoxy; n-hexoxy; n-heptoxy; n-octoxy; or combinations thereof.

The C₃-C₂₀ unsubstituted or substituted cyclic or heterocyclic group in formula (II) may include a C₃-C₁₈, C₆-C₁₄, or C₆-C₈ unsubstituted or substituted cyclic or heterocyclic group. Examples of unsubstituted or substituted cyclic or heterocyclic groups include cyclopropyl, cyclobutyl, cyclopentyl, methylcyclopentyl, cyclohexyl, methylcyclohexyl, dimethylcyclohexyl, cycloheptyl, cyclooctyl, cyclononyl, cyclodecyl, 1-adamantyl, 2-adamantyl, piperdyl, tetrahydrofuran, piperazinyl, morpholinyl, cyclopentyloxy, cyclohexyloxy, cycloheptyloxy, cyclooctyloxy or mixtures thereof. Unsaturated variants may be derived from these structures by substraction of a hydrogen atom on 2 adjacent ring members with formation of a double bond between them, an example for such a moiety is cyclohexenyl.

The C₆-C₃₀ unsubstituted or substituted aromatic group in formula (II) may include a C₆-C₂₀, C₆-C₁₈, C₆-C₁₄, or C₆-C₁₀ unsubstituted or substituted aromatic group. Examples include phenyl; biphenyl; o-, m-, or p-terphnyl; 1-naphthyl; 2-naphthyl; 1-, 2-, or 9-anthryl; 1, 2, 3, 4, or 9-phenanthrenyl; 1, 2, or 4-pyrenyl; or combinations thereof.

The C₅-C₃₀ unsubstituted or substituted heteroaromatic group in formula (II) may include a C₅-C₂₀, C₅-C₁₆, C₅-C₁₂, or C₅-C₈ unsubstituted or substituted heteroaromatic group. Examples include 2- or 3-furanyl; 2- or 3-thienyl; N-, 2- or 3-pyrroyl; 2- or 3-benzofuranyl; 2- or 3-benzothienyl; N-, 2-, or 3-indolyl; 2-, 3-, or 4-pyridyl; 2-, 3-, or 4-quinolyl; 1-, 3-, or 4-isoquinlyl; 2-benzoxazolyl; 2-, 4-, or 5-(1,3-oxazolyl); 2-, 4-, or 5-(1,3-thiazolyl); 2-benzothiazolyl; 3-, 4-, or 5-isoxazolyl; N-, 2-, or 4-imidazolyl; N-, or 2-benimidazolyl; 1-, or 2-naphthofuranyl; 1-, or 2-naphthothieyl; N-, 2- or 3-benzindolyl; 2-, 3-, or 4-benzoquinolyl; or combinations thereof.

Preferably, R₁₁ through R₁₆ in formula (II) are each independently selected from H, —CN, —COOH, —OH, a halogen, methyl, ethyl, propyl isopropyl, perfluoromethyl, phenyl, a substituted phenyl, naphthyl, a substituted naphthyl, methoxy, ethoxy, styryl, pyridyl, substituted pyridyl, thienyl, a substituted thienyl, pyrrolyl, a substituted pyrrolyl, ester, sulfonate, nitro, amine, an amide, or combinations thereof.

Preferably, R₁₂ and R₁₅ in formula (II) are each independently electron-withdrawing groups selected from trihalides, amides, esters, ammoniums, quaternary amines, quanternary ammonium bases, sulfonates, —SO₃H, —CN, or —NO₂. More preferably, R₁₂ and R₁₅ in formula (II) are each independently selected from the following structure: —CN, —NO₂, esters, amides, trifluoromethyl, and sulfonates.

Preferably, X₁ in formula (II) is CR₁₇, wherein R₁₇ is selected from H, —CN, methyl, ethyl, phenyl, a substituted phenyl, naphthyl, a substituted naphthyl, a C₁-C₃ unsubstituted or substituted alkyl, a C₁-C₄ unsubstituted or substituted alkenyl, thiol, a hetercyclic group, or a heteroaromatic group. More preferably, R₁₇ is methyl. Also preferably, R₁₇ is a C₆-C₁₀ unsubstituted or substituted aromatic group, for example, phenyl or a substituted phenyl.

X₂ and X₃ in formula (II) can be each independently selected from F, methyl, ethyl, n-propyl, iso-propyl, n-butyl, adamantyl, an unsubstituted or substituted phenyl, C₁-C₆ alkyoxy, methoxy, an unsubstituted or substituted ethynyl, ethynyltoluene, ethynylpyrene, and ethynylphenyl. Preferably, X₂ and X₃ are each F.

D in formula (I) may derive from one of the following light emitting compounds:

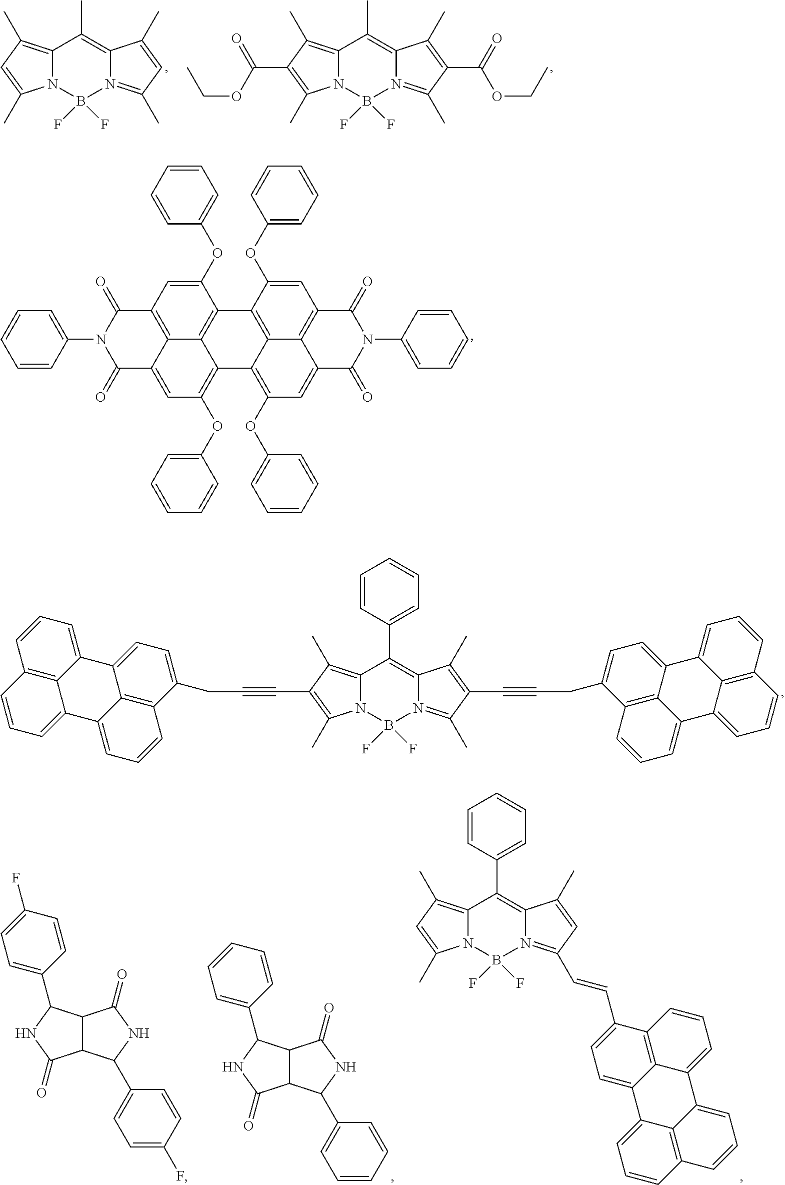

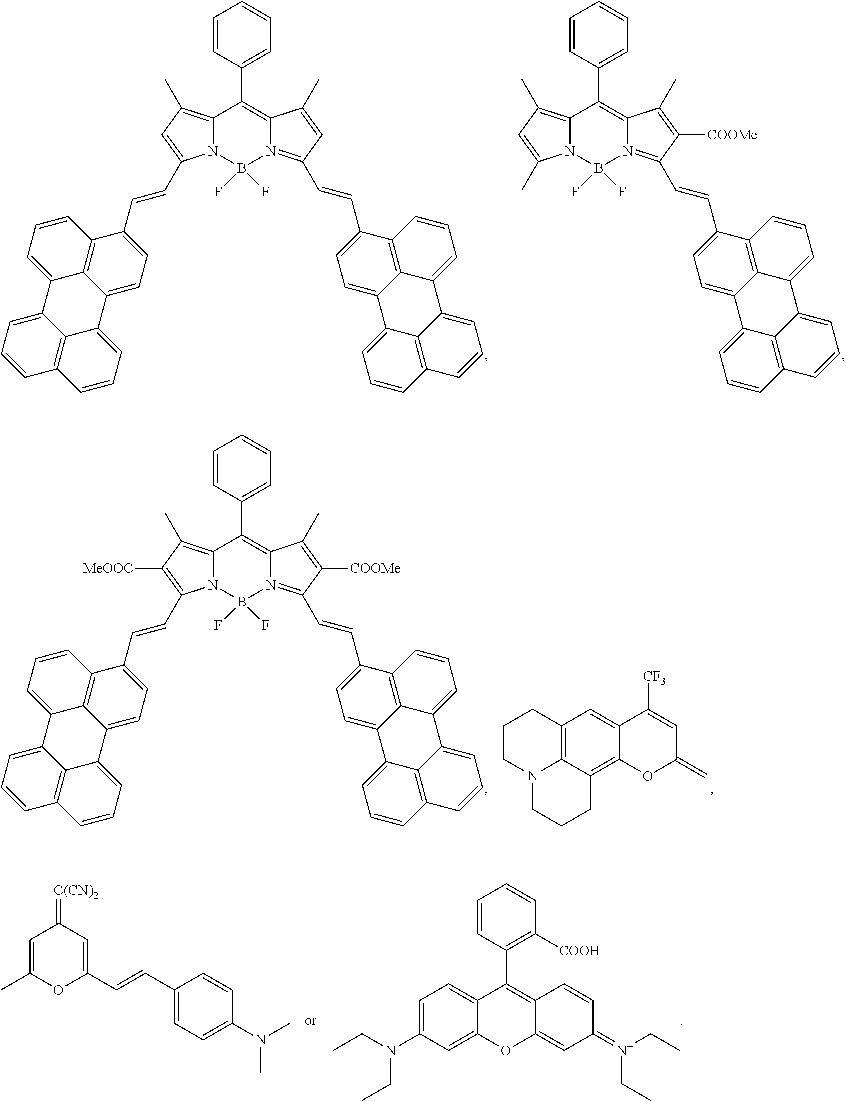

The functionalized light emitting compound useful in the present invention may be prepared by known processes, in which the light emitting compound described above is attached with one or more than one reactive group, such as an allyl group, forming the reactive light emitting compound which then reacts with a reactive organic silane compound to form the functionalized light emitting compound. The reactive organic silane compound useful in forming the functionalized light emitting compound has at least one functional group which can react with the reactive group of the reactive light emitting compound to form a covalent bond, for example, —Si—C—. The reactive organic silane compound has the general formula R₍₄₋ₙ₎SiXₙ, where X is a hydrolyzable substituent as described above in the functionalized light emitting compound section, such as ethoxy, methoxy, or 2-methoxy-ethoxy; R can be H, a monovalent organic group having from 1 to 12 carbon atoms which can optionally contain a functional organic group such as, for example, mercapto, epoxy, acrylyl, methacrylyl, and amino; and n is an integer of from 1 to 4, preferably an integer from 2 to 4. Examples of suitable reactive organic silane compounds include tetramethoxysilane (TMOS), tetraethoxysilane (TEOS), methyltrimethoxysilane (MTMS), methyltriethoxysilane (MTES), HSi(OEt)₃, or mixtures thereof. In one embodiment, the reactive organic silane compound is HSi(OEt)₃.

The first precursor useful in preparing the nanoparticles of the present invention is selected from a first organic silane compound having the structure of SiX¹₄, a first organic metal compound of MX¹₄ or MX¹₃ or mixtures thereof; wherein X¹ may be the same or different and each independently a hydrolyzable substituent, and M is selected from Al, Zr, Ti, or combinations thereof. X¹ may include those groups described above for X in formula (I), and preferably X¹ is a C₁-C₁₈ alkoxy.

The first organic silane compound useful in preparing the nanoparticles of the present invention can form silica under hydrolysis conditions. Examples of suitable first organic silane compounds include unsubstituted or substituted tetra-C₁-C₈ alkoxysilanes such as tetramethoxysilane (TMOS), tetraethoxysilane (TEOS), tetra-n-propoxysilane, and tetra-n-butoxysilane; tetrakis(methoxyethoxy)silane; tetrakis(ethoxyethoxy)silane; tetrakis(methoxyethoxyethoxy)silane; tetrakis(methoxypropoxy)silane; tetrakis(2-methyl-hexoxy)silane; di-C₁-C₄ alkyl-tetra-C₁-C₈ alkoxydisilanes such as dimethyltetraethoxydisiloxane; tetra-C₁-C₄ acyloxysilanes such as tetraacetoxysilane; tetra-C₂-C₄ alkenyloxysilanes such as tetraallyloxysilane; mixtures thereof. The first organic silane compound is preferably TEOS, TMOS, or a mixture thereof.

Under hydrolysis conditions, the first organic metal compound can form Al₂O₃, ZrO₂, or TiO₂. Examples of suitable first organic metal compounds include tri-C₁-C₄ alkoxy aluminate like tri-n-, -i-propoxy aluminate, tri-n-butoxyaluminate, like di-C₁-C₄ alkoxy aluminoxy tri-C₁-C₄ alkoxy silanes such as dibutoxy-aluminoxy-triethoxy-silane; tetra-n-butoxy zirconate, tetraethoxy zirconate, and tetra-n-, -i-propoxy zirconate; tetra-C₁-C₄ alkoxy zirconate such as tetra-n-butyl titanate, tetraethoxy titanate, tetramethoxy titanate, and tetra-n-, -i-propoxy titanate; or mixtures thereof.

The first precursor useful in preparing the nanoparticles of the present invention can be a mixture of one or more first organic silane compounds and one or more first organic metal compounds. In such mixture, the molar ratio of the first organic silane compound to the first organic metal compound in the first precursor may be from 0.001:1 to 1000:1, from 0.01:1 to 100:1, from 0.1:1 to 10:1, or from 1:1 to 8:1. Preferably, the first precursor comprises TEOS and an organic zirconia. Also preferably, the first precursor comprises TEOS and an organic titania. The molar ratio of the functionalized light emitting compound to the first precursor may be from 0.0001:1 to 0.05:1, from 0.0001:1 to 0.005:1, or from 0.0002:1 to 0.002:1.

The second precursor useful in preparing the nanoparticles of the present invention comprises (a) a second organic silane compound having the structure of SiX²₄ and (b) a second organic metal compound of MX²₄ or MX²₃, wherein each X² is independently a hydrolyzable substituent, and M is selected from Al, Zr, Ti, or combinations thereof. X² may include those groups described for X in formula (I). The second organic silane compound may be the same as or different from the first organic silane compound and may include those useful as the first organic silane compound. The second organic metal compound may be the same or different from the first organic metal compound and may include those useful as the first organic silane compound. Preferably, an organic zirconia, ZrX²₄, such as zirconium n-butoxide is used as the second metal compound. Also preferably, an organic titania, TiX²₄, such as tetrabutyl orthotitanate is used as the second metal compound. The molar ratio of the second organic silane compound to the second organic metal compound in the second precursor may be from 0.001:1 to 1000:1, from 0.01:1 to 100:1, from 0.1:1 to 10:1, or from 1:1 to 8:1. The molar ratio of the first precursor to the second precursor may be from 100:1 to 0.01:1, from 10:1 to 0.1:1, or from 10:1 to 1:1.

The process useful for preparing the nanoparticles of the present invention comprises step (i) providing one or more functionalized light emitting compounds described above. The process further comprises step (ii) pre-hydrolyzing the functionalized light emitting compound, which may be conducted by treating the functionalized light emitting compound in the presence of a catalyst, preferably a base catalyst, for a period of time. The time duration for pre-hydrolyzing the functionalized light emitting compound may vary depending on the type of the functionalized light emitting compound and should not cause aggregation of the functionalized light emitting compound does not aggregate, for example, 1 minute (min) or longer, 10 min or longer, or even 15 min or longer, and at the same time, 3 hours (h) or shorter, 2 h or shorter, 1 h or shorter, or even 45 min or shorter. Suitable catalysts may be selected from ammonia, amines or other alkalis. Preferred catalyst is ammonia. This reaction is generally carried out in the presence of a solvent. Preferred solvents are organic solvents. Examples of suitable solvents include alcohols such as ethanol, methanol, 1-propanol, 2-propanol, 1-methoxy-2-propanol, or mixtures thereof. In one embodiment, ethanol is used as the solvent.

The process useful for preparing the nanoparticles of the present invention further comprises step (iii) adding the first precursor to the obtained pre-hydrolyzed functionalized light emitting compound. Usually the first precursor undergoes hydrolysis and co-condenses with the functionalized light emitting compound to form the core of the nanoparticles. This reaction is generally conducted by known sol-gel chemistry, e.g., by hydrolysis of the first organic silane compound and/or the first organic metal compound. The reaction can be carried out in the presence of a solvent including those described above useful in the step (ii) pre-hydrolyzing the functionalized light emitting compound. The concentration of the first precursor may be in a range of, based on the volume of the solvent, from 0.05 to 1 mol/L, from 0.1 to 0.8 mol/L, or from 0.1 to 0.5 mol/L. The time duration for such reaction may be in the range of from 1 h to 48 h, from 1 h to 24 h, or from 2 h to 12 h. The core of the nanoparticles may comprise an inorganic matrix obtained by hydrolysis of the first precursor and the luminophore D attached to the inorganic matrix through a covalent bond.

The process useful for preparing the nanoparticles of the present invention further comprises step (iv) adding the second precursor. The second precursor undergoes hydrolysis and condensation to obtain the nanoparticles of the present invention. This reaction is generally carried out in the presence of a solvent including those described above useful in the step (ii) pre-hydrolyzing the functionalized light emitting compound. Preferred solvent is ethanol. Time duration for such reaction may be in the range of from 1 h to 48 h, from 1 h to 24 h, or from 2 h to 12 h. The second precursor is useful in forming the shell of the nanoparticles of the present invention.

The process for preparing the nanoparticles of the present invention may be, for the step (ii), (iii) and (iv), respectively, conducted at a temperature in the range of 20° C. to 100° C., 40° C. to 70° C., or 50° C. to 60° C.

The process for preparing the nanoparticles of the present invention may further comprise a surface modification step, that is, (v) adding a surface modifier having the structure of R¹ₘSi (R²)₄₋ₘ, wherein each R¹ is independently selected from a C₁-C₂₀ unsubstituted or substituted alkyl, a C₂-C₂₀ unsubstituted or substituted alkenyl, or a C₆-C₂₄ unsubstituted or substituted aryl group; each R² is independently a hydrolysable groups; and m is an integer of 1 to 3. For example, each R² is independently selected from a halogen; methoxy; ethoxy; n-, i-propoxy; n-, i-, sec.-, tert.-butoxy; n-pentoxy; n-hexoxy; n-heptoxy; n-octoxy; preferably for C₁-C₄ alkoxy such as for methoxy; ethoxy; n-propoxy; n-butoxy; formyloxy; acetoxy; n-, i-propoyloxy; n-, i-, sec.-, tert.-butoyloxy; n-pentoyloxy; n-hexoyloxy; or acetoxy.

Preferred surface modifiers useful in preparing the nanoparticles of the present invention include n-C₁-C₁₈ alkyl-tri(C₁-C₈ alkoxy)silanes such as methyltrimethoxysilane (MTMS), methyltriethoxysilane (MTES), ethyl-trimethoxysilane, ethyl-triethoxysilane, n-propyl-trimethoxysilan, n-propyl-triethoxysilan, nbutyl-trimethoxysilane, n-octyl-trimethoxysilane, n-octadecyl-trimethoxysilane, n-butyl-triethoxysilane, n-octyltriethoxysilane, n-octadecyl-triethoxysilane, NH₂(CH₂)₃Si(OCH₃)₃, CH₂CHCH₂O(CH₂)₃Si(OCH₃)₃, CH₂═C(CH₃)COO(CH₂)₃Si(OCH₃)₃, NH₂(CH₂) 2NH(CH₂)₃Si(OCH₃)₃, HS(CH₂)₃Si(OC₂H₅)₃, NH₂(CH₂)₂NH(CH₂)₃SiCH₃ (OCH₃)₂, CH₂═CHSi(OCH₃)₃, or mixtures thereof. In one embodiment, MTMS or MTES is used as the surface modifier. The dosage of the surface modifier is, based on the weight of the first precursor, in the range of from 5% to 150% by weight, from 10% to 100% by weight, or from 30% to 100% by weight. The step of surface modification may be conducted at a temperature in the range of 20° C. to 100° C., 40° C. to 80° C., or 50° C. to 70° C.

The nanoparticles of present invention may comprise a core and a shell. The core may comprise a reaction product of the functionalized light emitting compound and the first precursor. The shell may encapsulate or at least partially encapsulate the core and may comprise the reaction product of the second precursor. In one aspect, the present invention provides a light emitting composition comprising the nanoparticles of the present invention, where the core of the nanoparticles comprises a reaction product of two or more functionalized light emitting compounds and the first precursor in order to achieve a desirable blend output of spectral emission colors. The nanoparticles of the present invention may have a particle size, that is, the diameter of the nanoparticles, in the range of from 10 to 2,000 nanometers (nm), from 20 to 200 nm, or from 30 to 100 nm. The particle size may be measured by dispersing the nanoparticles into ethanol through a scanning transmission electron microscopy. The nanoparticles preferably have a unimodal distribution. The nanoparticles may have a polydispersity index less than 0.7, less than 0.5, or even less than 0.2, as measured by dynamic light scattering. The nanoparticles of the present invention may be spherical. The thickness the core to the thickness of the shell can be in a ratio of, for example, from 100:1 to 1:100, from 10:1 to 1:10, or from 10:1 to 2:1.

The present invention also provides nanoparticles having a particle size in the range of from 10 to 2,000 nm, wherein the nanoparticles comprise: a core comprising a reaction product of one or more than one functionalized light emitting compounds and the first precursor; and a shell comprising a reaction product of the second precursor, wherein the second precursor comprises the second organic silane compound and the second organic metal compound and the molar ratio of the second organic silane compound to the second organic metal compound is from 1:1 to 50:1.

The nanoparticles of the present invention may be useful in the fields of decoration, security, package, electronic materials and devices, bio-imaging, fluorescent art painting, and color conversion materials for displays.

The nanoparticles of the present invention can exhibit a full width at half maximum (FWHM) less than 100 nm, less than 90 nm, less than 70 nm, or even less than 50 nm; and have an absorption of at least 1000 M⁻¹ cm⁻¹ in a spectral region of 430-490 nm. In one embodiment, the nanoparticles of the present invention show better photostability than nanoparticles obtained from the same process of the present invention except that the second precursor only comprises the second silane compound.

The present invention also provides a light emitting composition comprising one or more than one types of the nanoparticles of the present invention, and optionally an additional light emitting material that is different from the nanoparticles. The additional light emitting materials may be selected from the group consisting of an organic emitter, an inorganic phosphor, a quantum dot, and a heterojunction nanorod or heterjunction nanocrystal.

The present invention also provides a blend of light emitting composition comprising one or more than one types of the nanoparticles of the present invention, and optionally an additional light emitting material that is different from the nanoparticles in order to achieve a desirable blend output of spectral emission colors. The additional light emitting materials may be selected from the group consisting of an organic emitter, an inorganic phosphor, a quantum dot, and a heterojunction nanorod or heterjunction nanocrystal. In one aspect, the present invention provides a blend of light emitting composition comprising one or more than one types of the nanoparticles of the present invention which gives a full spectral output approximating the appearance of white light to the human visual system. In another aspect, the present invention provides a blend of light emitting composition comprising one or more than one types of the nanoparticles of the present invention which gives a full spectral output approximating enriched in a particular color so that the appearance of white light to the human visual system is a warmer, red or yellow color. In another aspect, the present invention provides a blend of light emitting composition comprising one or more than one types of the nanoparticles of the present invention which gives a full spectral output approximating enriched in a particular color so that the appearance of white light to the human visual system is a colder, blue-ish color.

The present invention also provides a film comprising the nanoparticles of the present invention. The film may further comprises a polymeric binder selected from polymethyl methacrylate (PMMA), polystyrene, silicone resin, acrylic resin, epoxy resin, or mixtures thereof. It is preferred that the polymer binder is transparent, or at least semi-transparent. Preferably, PMMA is used as the binder. The film may be prepared by gap coating, drop coating, spray coating, or spin coating.

The present invention also provides an electronic device comprising a layer of the nanoparticles of the present invention. The layer may further comprise one more polymeric binder, additives, or mixtures thereof. The polymeric binder may include those used in the film described above. Examples of suitable additives include antioxidants, radical scavengers, inorganic filler particles, organic filler particles, or mixtures thereof. The dosage of the additives may be in an amount of from 0 to 10% by weight, from 0 to 8% by weight, or from 0.01% to 5% by weight, based on the weight of the nanoparticles of the present invention. The electronic device of the present invention can be an organic electronic device or an inorganic electronic device. The electronic device may be selected from a liquid crystal display device, an organic light-emitting device, and an inorganic light-emitting device.

The present invention also provides a light emitting apparatus comprising a layer comprising the nanoparticles of the present invention. The layer comprising the nanoparticles in the light emitting apparatus may be embedded in a film formed by one or more polymeric binders described above. The light emitting apparatus may further comprise a barrier layer which substantially excludes the transport of water or oxygen molecules.

The present invention also provides a backlight unit for a display apparatus comprising the light emitting apparatus described above. Preferably, the backlight unit comprises the layer of the nanoparticles of the present invention.

### EXAMPLES

Some embodiments of the invention will now be described in the following Examples, wherein all parts and percentages are by weight unless otherwise specified. The following materials are used in the examples:

| | Specification or | | |
|---|---|---|---|
| Chemical Name | structure | CAS No. | Supplier |
| Tetraethyl orthosilicate (TEOS) | ≥99% | 78-10-4 | Sigma Aldrich |
| Zirconium n-butoxide | 80 wt % in butanol | 1071-76-7 | Sigma Aldrich |
| Tetrabutyl Orthotitanate (TBOT) | ≥97% | 5593-70-4 | Sigma Aldrich |
| Boron-dipyrromethene (BODIPY) | 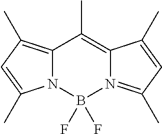 | 121207-31-6 | TCI Chemicals |
| | >98.0% (GC) | | |
| Anhydrous ethanol | ≥99.9% | 64-17-5 | SCRC |
| 2-Propanol | ≥99.9% | 67-63-0 | SCRC |
| Ammonia | 25-28 wt % | 1336-21-6 | SCRC |
| Methyltrimethoxysilane (MTMS) | ≥98% | 1185-55-3 | Sigma Aldrich |
| Methyltriethoxysilane (MTES) | ≥99% | 2031-67-6 | Sigma Aldrich |
| n-Propyltrimethoxysilane (MPTS) | ≥97% | 1067-25-0 | Sigma Aldrich |
| Propylene glycol monomethyl | >98% (GC) | 108-65-6 | TCI Chemicals |
| ether acetate (PGMEA) | | | |
| POCl₃ | ReagentPlus ®, 99% | 10025-87-3 | Sigma Aldrich |
| N,N-Dimethylformamide (DMF) | AR | 68-12-2 | SCRC |
| 1,2-dichloroethane (DCE) | AR | 107-06-2 | SCRC |
| Dichloromethane (DCM) | AR | 75-09-2 | SCRC |
| Allyl bromide | ≥98% (GC) | 106-95-6 | Sigma Aldrich |
| Zn dust | ≥98% | 7440-66-6 | Sigma Aldrich |
| NH₄Cl | AR | 12125-02-9 | SCRC |
| NaHCO₃ | AR | 144-55-8 | SCRC |
| Na₂SO₄ | AR | 7757-82-6 | SCRC |
| Tetrahydrofuran (THF) | AR | 109-99-9 | SCRC |
| Ethyl acetate (EA) | AR | 141-78-6 | SCRC |
| Trimethoxysilane | AR | 2487-90-3 | Sigma Aldrich |
| Pt/C catalyst | 5% Pt loading | — | TCI |
| Methanol | AR | 67-56-1 | SCRC |
| 2,3-dicyano-5,6- | 98% | | SCRC |
| dichlorobenzoquinone (DDQ) | | | |

*SCRC represents Sinopharm Chemical Reagent Co. Ltd.

The following standard analytical equipment and methods are used in the Examples:

Characterization of Nanoparticles

Dynamic light scattering (DLS, Malvern Zetasizer Nano) is employed for particle size distribution analysis of the nanoparticles.

Scanning transmission electron microscopy (STEM, Nova™ NanoSEM 630) is employed for the particle morphology and size analysis of the nanoparticles.

The absorption and emission spectra of the nanoparticles are characterized by UV—VIS-NIR spectrophotometer (SHIMADZU UV3600) and spectrofluorometer (HORIBA FluoroMax-4), respectively.

Photostability Test

To mimic the real situation, a blue backlight unit (from QD enhanced LCD device) plus two optical intensified films is used as the light source with light intensity of 1450-1500 Cd/m². PMMA/nanoparticles containing films and PMMA/an emitter (without encapsulation) containing films, respectively, are placed in front of the blue backlight unit for continuous irradiation in open air. The peak intensity of photoluminescence spectrum is tracked over time with spectrofluorometer (HORIBA FluoroMax-4).

Reliability Test

The reliability test is conducted via the following steps: 1) Cut each sample film into 4 pieces and then put them into a closed chamber at the same time; 2) Keep the chamber at high relative humidity (RH) and temperature: 90% RH, 60° C.; and 3) Every 100 h, a piece of each sample is taken out for photoluminescent test. The peak intensity of photoluminescence spectrum of the sample is tracked over time with spectrofluorometer (HORIBA FluoroMax-4).

Synthesis of Functionalized Light Emitting Compound (LEC) 1

POCl₃ (2 mL) was added dropwise to a vigorously stirring anhydrous DMF (2 mL) which was kept in ice bath under N₂. Resulting pale yellow viscous liquid was allowed to stir at room temperature for additional 30 min. To this, DCE (50 mL) solution of BODIPY (524 mg, 2.0 mmol) was then slowly introduced and the resultant brown solution was heated at 60° C. for 3 h. The resulting solution was cooled to room temperature, and poured into ice-cold saturated NaHCO₃ solution. This mixture was extracted twice with dichloromethane (100 mL portions) and dried over anhydrous Na₂SO₄. Solvent was then evaporated in vacuo and the residue was purified by silica gel using dichloromethane as the eluent to afford the formyl functionalized product.

To a stirred mixture of the obtained formyl functionalized product (87 mg, 0.3 mmol), allyl bromide (181.5 mg, 1.5 mmol), and Zn dust (325 mg, 1.5 mmol) in THF (5 mL) was dropwise added aqueous saturated NH₄C₁ (5 mL) at ambient temperature. (21-25° C.) After being stirred vigorously for 1 h, the mixture was filtrated and extracted with ethyl acetate. The organic extract washed with water and brine and dried over Na₂SO₄. Solvent was removed and the residue was purified by column chromatography (eluent: dichloromethane) with silica gel to obtain an allyl functionalized product (97 mg, 97% yield).

To a nitrogen (N₂) protected Schlenk tube was added the above synthesized allyl functionalized product (34 mg, 0.1 mmol), Pt/C (17 mg, 5% Pd loading), MeOH (2 mL), and HSi(OEt)₃ (0.5 mL) sequentially. The resulting mixture was allowed to reflux overnight. After that, TLC analysis was carried out. All starting materials were consumed at that time. Filtration and evaporation afforded the crude product of Functionalized LEC 1. To avoid hydrolysis of silane structure, column chromatography was not carried out. The crude product was gained with 83 mg. Schematic of synthesis of Functionalized LEC 1 is shown as below:

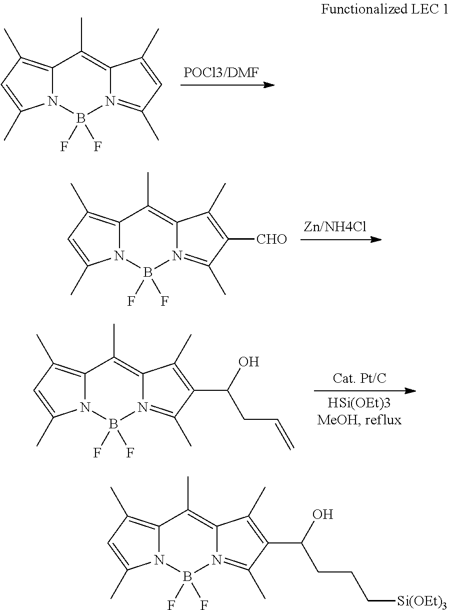

Synthesis of Functionalized LEC 2

To a solution of 4-hydroxybenzaldehyde (4.0 g, 32.7 mmol, 1.0 equiv) in acetone (40 mL), K₂CO₃ (13.6 g, 3.0 equiv) and allyl bromide (4.3 mL, 1.5 equiv) were added. The reaction mixture was stirred at room temperature for 2 h and further heated to reflux overnight. After cooling to room temperature, the solution was filtered, washed with acetone and concentrated in vacuo, which afford 4-(allyloxy)benzaldehyde.

A few drops of trifluoroacetic acid were added to a 200 mL of dichloromethane solution of ethyl 2,4-dimethyl-1H-pyrrole-3-carboxylate (2.1 g, 2.0 equiv) and aldehyde (1.0 g, 1.0 equiv). The dark reaction mixture was stirred at room temperature until total disappearance of the aldehyde. The oxidizing agent (DDQ, 1.4 g), then 30 min later 13.0 mL Et3N and finally 15.0 mL trifluoroborate etherate were successively added. The mixture was filtered through a pad of silica or used crude. The filtrate was concentrated and the residue was purified by chromatography on silica or alumina gel or by automatic chromatography to afford an allyl functionalized BODIPY (yield, 75%).

100 mg of the above synthesized allyl functionalized BODIPY (0.2 mmol) was dissolved into toluene. Under N₂, HSi(OEt)₃ (125 mg, 4.0 equiv) was injected through a septum, followed by the addition of a drop of Karstedt's catalyst (platinum divinyltetramethy-siloxane complex in xylene, 3 weight percent (wt %)). The resulting mixture was stirred at 60° C. overnight. The solution was evaporated under reduced pressure. The crude product of Functionalized LEC 2 was obtained without further purification. Schematic of synthesis of Functionalized LEC 2 is shown as below:

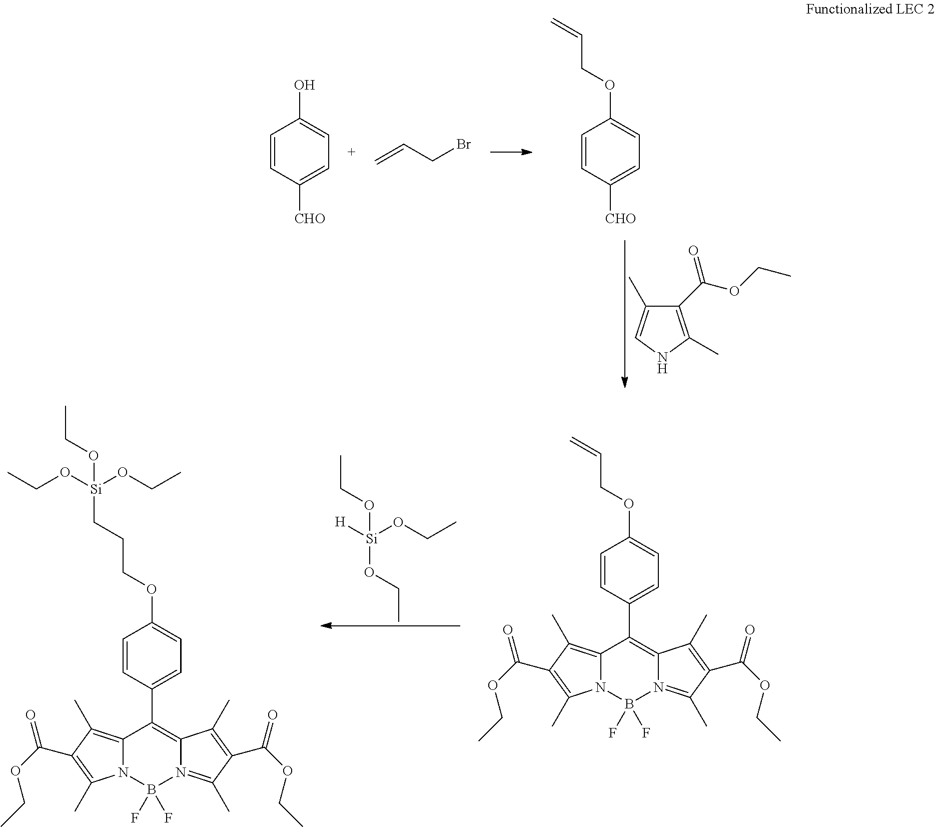

### Example (Ex) 1

70 ml ethanol was added to 250 ml three-neck flask, followed by 5 ml ammonia. The mixture was slowly stirred while heated to 50° C. Calculated amount of Functionalized LEC 1 dissolved in 30 ml ethanol was added to the reaction flask stirred for 15-20 min at 50° C. Then 3 ml TEOS was added into the flask reactor. The resulting mixture was stirred for 3 h at 50° C. 2 ml TEOS and 305 μl of TBOT were dissolved into 18 ml isopropanol (IPA) and then dropped into the reaction flask in 180 min by peristaltic pump, and kept stirring at 50° C. overnight. 2.7 ml of MTMS was added into the reaction flask and kept stirring at 50° C. for 4-5 h. The obtained colloidal suspension was collected via centrifuge and washed with ethanol three times.

### Ex 2

70 ml ethanol was added to 250 ml three-neck flask, followed by 5 ml ammonia. The mixture was slowly stirred while heated to 50° C. Calculated amount of Functionalized LEC 1 dissolved in 30 ml ethanol was added to the reaction flask stirred for 15-20 min at 50° C. Then 3 ml TEOS was added into the flask reactor. The resulting mixture was stirred for 3 hs at 50° C. 2 ml TEOS and 410 μl of zirconium n-butoxide solution were dissolved into 18 ml IPA, then dropped into the reaction flask in 180 min by peristaltic pump and kept stirring at 50° C. overnight. 2.7 ml of MTMS was added into the reaction flask and kept stirring at 50° C. for 4-5 h. The obtained colloidal suspension was collected via centrifuge and washed with ethanol three times.

### Ex 3

70 ml ethanol was added to 250 ml three-neck flask, followed by 5 ml ammonia. The mixture was slowly stirred while heated to 50° C. Calculated amount of Functionalized LEC 2 dissolved in 30 ml ethanol was added to the reaction flask stirred for 15-20 min at 50° C. Then 3 ml TEOS was added into the flask reactor. The resulting mixture was stirred for 3 h at 50° C. 2 ml TEOS and 305 μl of TBOT were dissolved into 18 ml IPA, then dropped into the reaction flask in 180 min by peristaltic pump and kept stirring at 50° C. overnight. 2.7 ml of methyl triethoxysilane was added into the reaction flask and kept stirring at 50° C. for 4-5 h. The obtained colloidal suspension was collected via centrifuge and washed with ethanol three times.

### Comparative (Comp) Ex A

70 ml ethanol was added to 250 ml three-neck flask, followed by 5 ml ammonia. The mixture was stirred while heated to 50° C. Calculated amount of Functionalized LEC 1 dissolved in 30 ml ethanol was added to the reaction flask stirred for 15-20 min at 50° C. Then 3 ml TEOS was added into the flask reactor. The resulting mixture was stirred for 3 h at 50° C. 2 ml TEOS was dissolved into 18 ml IPA, then dropped into the reaction flask in 180 min by peristaltic pump, and kept stirring at 50° C. overnight. 2.7 ml of MTES was added into the reaction flask and kept stirring at 50° C. for 4-5 h. The obtained colloidal suspension was collected via centrifuge and washed with ethanol three times.

### Comp Ex B

70 ml ethanol was added to 250 ml three-neck flask, followed by 5 ml ammonia. The mixture was stirred while heated to 50° C. Calculated amount of Functionalized LEC 2 together with 400 μl of MPTS and 400 μl of MTMS were dissolved into 30 ml ethanol and then added to the reaction flask and stirred for 60 min at 50° C. Then 2.2 ml TEOS was added into the flask reactor. The mixture was stirred for 3 h at 50° C. The reaction was stopped since the mixture gelled.

### Comp Ex C

50 ml IPA was added to 250 ml three-neck flask, followed by 30 ml DI water and 10 ml ammonia. The mixture was stirred at room temperature. Calculated amount of Functionalized LEC 2 together with 400 μl of MPTS and 400 μl of MTMS were dissolved into 30 ml IPA and then added to the reaction flask stirred at 600 rpm and at room temperature for 24 h. 2.5 ml TEOS was dissolved into 25 ml IPA and then added into the reaction flask. Afterwards, this reaction mixture is stirred for 24 h.

### Comp Ex D

70 ml ethanol was added to 250 ml three-neck flask, followed by 5 ml ammonia. The mixture was slowly stirred while heated to 50° C. Calculated amount of Functionalized LEC 2 dissolved in 30 ml ethanol was added to the reaction flask, followed by adding 3 ml TEOS into the flask. The resulting mixture was stirred for 3 h at 50° C. 2 ml of TEOS and 305 μl of TBOT were dissolved into 18 ml IPA then dropped into the reaction flask in 180 min by peristaltic pump and kept stirring at 50° C. overnight. 2.7 ml of methyl triethoxysilane was added into the reaction flask and kept stirring at 50° C. for 4-5 h. The obtained colloidal suspension was collected via centrifuge and washed with ethanol three times.

The as-prepared nanoparticles of Exs 1-3 and Comp Exs A and D, respectively, were dissolved into PGMEA to form a clear solution. Then the solution of nanoparticles was homogeneously mixed with PMMA solution (30 wt % in PGMEA) and coated onto a polyethylene terephthalate (PET) film, then dried in an oven to evaporate PGMEA solvent. No barrier film that would improve the barrier properties of the nanoparticles-containing PMMA film was used. The thickness of dried nanoparticles-containing PMMA films was around 80-100 μm.

### Comp Exs E and F

Functionalized LEC 1 and Functionalized LEC 2, respectively, were dissolved into PGMEA to form clear solutions. Then the solutions were each homogeneously mixed with PMMA solution (30 wt % in PGMEA) and coated onto a PET film, then dried in an oven to evaporate PGMEA solvent. No barrier film that would improve the barrier properties of the PMMA film was used. The thickness of the dried films was around 80-100 μm.

Table 1 shows typical DLS results of Ex 3 at different synthetic stage. The as prepared nanoparticles have a unimodal distribution with core particle size of around 48 nm and shell layer thickness of around 8 nm. After surface modification, the final particle size is around 58 nm. Since the particle size obtained from DLS was hydrodynamic diameter, the particle size obtained from DLS was bigger than that obtained from STEM (20-40 nm).

TABLE 1

| | Particle Size | |
|---|---|---|
| Ex 3 | (Z-average)/nm | Polydispersity index (PDI) |
| Core | 48 | 0.188 |
| Core-shell | 56 | 0.138 |
| Final product (after | 58 | 0.163 |
| surface modification) | | |

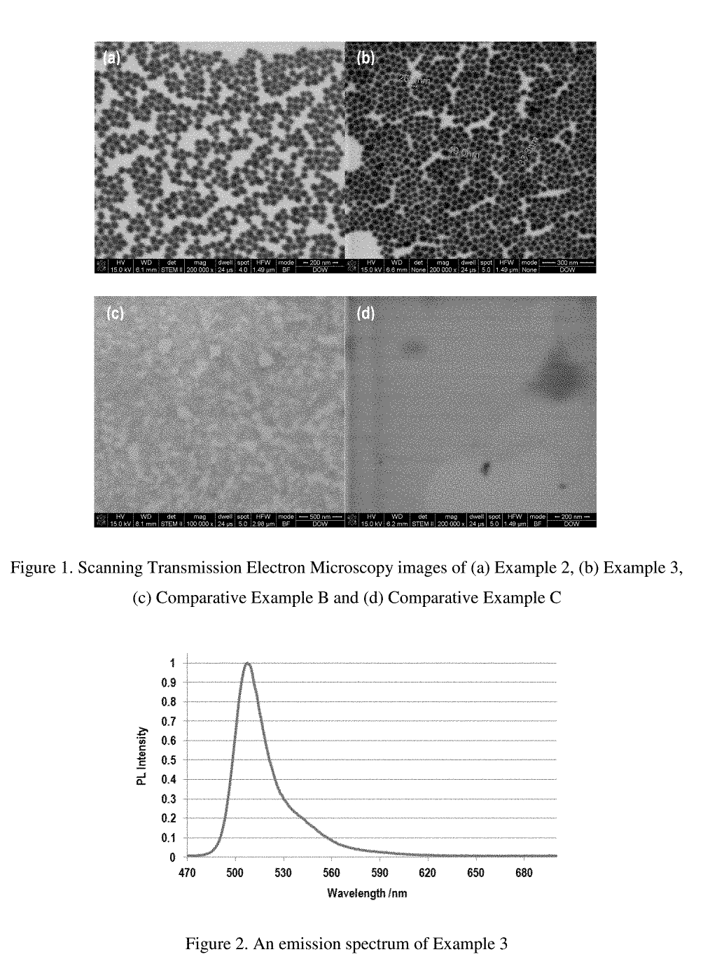

FIG. 1 shows STEM images of Exs 2 and 3 and Comp Exs B and C. Table 2 summarizes properties of the products obtained from Exs 1-3 and Comp Exs A-D. As seen from FIG. 1 and shown in Table 2, Exs 2 and 3 showed mono-dispersed nanoparticles with particle size around 30-50 nm. In contrast, the product obtained from Comp Ex B gelled, thus no particles were formed in Comp Ex B. Almost no particle formed in Comp Ex C.

TABLE 2

| Sample No. | Particle Morphology | Particle Size (nm) |
|---|---|---|
| Ex 1 | Spherical | 30-50 |
| Ex 2 | Spherical | 30-50 |
| Comp Ex A | Spherical | 30-50 |
| Ex 3 | Spherical | 30-50 |
| Comp Ex B | Gel, no particle formed | — |
| Comp Ex C | Almost no particle formed | — |
| Comp Ex D | Spherical | 30-50 |

FIG. 2 shows emission spectra of nanoparticles of Ex 1. As seen from FIG. 2, the as prepared fluorescent nanoparticles were highly emissive with fluorescent quantum yield of over 85%. The FWHM of the emission spectrum of the nanoparticles of Ex 1 was only 23 nm which is applicable in LCD devices.

Table 3 gives photostability properties of Functionalized LEC 1 (Comp Ex E), nanoparticles of Ex 1, and nanoparticles of Comp Ex A under the blue light irradiation (1450 Cd/m²). As shown in Table 3, the nanoparticles having a hybrid shell (Ex 1) showed better photostability than those having pure silica shell (Comp Ex A). Compared to Functionalized LEC 1 without encapsulation (Comp Ex E), Ex 1 showed significantly improved photostability, which indicates the effectiveness of encapsulation.

TABLE 3

| | Photostability (hour, with 80% retention of |
|---|---|
| Sample name | initial light intensity) |
| Comp Ex E | 26 |
| Ex 1 | 140 |
| Comp Ex A | 113 |

Table 4 shows the photostability properties of films comprising nanoparticles of Ex 3 or Comp Ex D after 340 hour irradiation by blue light. As shown in Table 4, nanoparticles of Ex 3 provided better photostability than those of Comp Ex D.

TABLE 4

| | Photostability (% of initial light intensity after 340 h |
|---|---|
| Sample name | irradiation by blue backlight) |
| Ex 3 | 64.3 |
| Comp Ex D | 55.7 |

Table 5 shows the reliability properties of films comprising nanoparticles of Ex 3 or Functionalized LEC 2 of Comp Ex F (without encapsulation). As shown in Table 5, the nanoparticles of Ex 3 provided better reliability than the Functionalized LEC 2 (Comp Ex F).

The results further indicate that encapsulation helps improve reliability.

TABLE 5

| | Reliability (% of initial light intensity after |
|---|---|
| Sample name | 406 h storage at 60° C. and 90% RH) |
| Ex 3 | 73 |
| Comp Ex F | 64 |

What is claimed is:

1. Nanoparticles prepared by a process comprising:
(i) providing a functionalized light emitting compound, wherein the functionalized light emitting compound has the structure of D-L-SiX₃, wherein D is a luminophore, L is a direct bond or an organic group, and X is a hydrolyzable substituent;
(ii) pre-hydrolyzing the functionalized light emitting compound;
(iii) adding a first precursor, wherein the first precursor is selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and
(iv) adding a second precursor, wherein the second precursor comprises (a) a second organic silane compound having the structure of SiX²₄, and (b) a second organic metal compound having the structure of MX²₃ or MX²₄; wherein each X² is independently a hydrolyzable substituent, and M is selected from Al, Zr, Ti, or combinations thereof; thus to obtain the nanoparticles.

2. The nanoparticles of claim 1, wherein the process further comprises:
(v) adding a surface modifier having the structure of R¹ₘSi(R²)₄₋ₘ, wherein R¹ is selected from a C₁-C₂₀ unsubstituted or substituted alkyl, a C₂-C₂₀ unsubstituted or substituted alkenyl, or a C₆-C₂₄ unsubstituted or substituted aryl group; R² is a hydrolysable group; and m is an integer of 1 to 3.

3. The nanoparticles of claim 1, wherein pre-hydrolyzing the functionalized light emitting compound is conducted by treating the functionalized light emitting compound in the presence of a base catalyst for a period of time between 1 minute to 3 hours.

4. The nanoparticles of claim 1, wherein the first precursor is a mixture of the first organic silane compound and the first organic metal compound.

5. The nanoparticles of claim 1, wherein the second precursor is a mixture of the second organic silane compound with TiX²₄ or ZrX²₄.

6. The nanoparticles of claim 1, wherein the molar ratio of the second organic silane compound to the second organic metal compound in the second precursor is from 1:1 to 50:1.

7. The nanoparticles of claim 1, wherein step (ii), (iii), and (iv) of the process are each independently conducted at a temperature in the range of 20 to 100° C.

8. The nanoparticles of claim 1, wherein D in the structure of D-L-SiX₃ is a luminophore derived from a light emitting compound having the structure of formula (II): 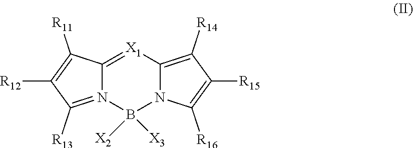
wherein R₁₁ through R₁₆ are each independently selected from H, a halogen, —CN, —CF₃, —NO₂, a C₁-C₂₄ unsubstituted or substituted alkyl, a C₂-C₂₄ unsubstituted or substituted alkenyl, a C₂-C₂₄ unsubstituted or substituted alkynyl, a C₁-C₂₄ unsubstituted or substituted alkoxy, a C₃-C₂₀ unsubstituted or substituted cyclic or heterocyclic group, —SO₃H, sulfonate, —SO₂O—, a thio ether, an ether, a urea, —CO₂H, an ester, an amide, an amine, a C₆-C₂₀ unsubstituted or substituted aromatic group, or a C₅-C₂₀ unsubstituted or substituted heteroaromatic group; R₁₁ and R₁₂ may join together to form a 5-, 6-, 7-membered ring together with the atoms they are bonded; R₁₂ and R₁₃ may join together to form a 5-, 6-, 7-membered ring together with the atoms they are bonded; R₁₄ and R₁₅ may join together to form a 5-, 6-, 7-membered ring together with the atoms they are bonded; and R₁₅ and R₁₆ may join together to form a 5-, 6-, 7-membered ring together with the atoms they are bonded;
wherein X₁ is N or CR₁₇, wherein R₁₇ is selected from H, a halogen, —CN, —CF₃, a C₁-C₂₄ unsubstituted or substituted alkyl, a C₂-C₂₄ unsubstituted or substituted alkenyl, a C₂-C₂₄ unsubstituted or substituted alkynyl, a C₁-C₂₄ unsubstituted or substituted alkoxy, a C₃-C₂₀ unsubstituted or substituted cyclic or heterocyclic group, a C₆-C₂₀ unsubstituted or substituted aromatic group, a C₅-C₂₀ unsubstituted or substituted heteroaromatic group, an ether, an ester, a carboxylic acid, —OH, an amide, an amine, or a sulfide; and
wherein X₂ and X₃ are each independently selected from a halogen, a C₁-C₂₄ unsubstituted or substituted alkyl, a C₂-C₂₄ unsubstituted or substituted alkenyl, a C₂-C₂₄ unsubstituted or substituted alkyne, a C₃-C₂₀ unsubstituted or substituted cyclic or heterocyclic group, a C₆-C₂₀ unsubstituted or substituted aromatic group, a C₅-C₂₀ unsubstituted or substituted heteroaromatic group, or a C₁-C₂₄ unsubstituted or substituted alkoxy; and X₂ and X₃ may join together to form a single substituent group.

9. The nanoparticles of claim 8, wherein R₁₂ and R₁₅ are each independently electron-withdrawing groups selected from trihalides, amides, esters, ammoniums, quaternary amines, quanternary ammonium bases, sulfonates, —SO₃H, —CN, or —NO₂.

10. The nanoparticles of claim 1, wherein the particle size of the nanoparticles is in the range of from 10 to 2,000 nm.

11. Nanoparticles having a particle size in the range of from 10 to 2,000 nm, wherein the nanoparticles comprise:
a core comprising a reaction product of a functionalized light emitting compound and a first precursor, wherein the functionalized light emitting compound has the structure of D-L-SiX₃, wherein D is a luminophore, L is a direct bond or an organic group, and X is a hydrolyzable substituent; and the first precursor is selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and
a shell comprising a reaction product of a second precursor, wherein the second precursor comprises (a) a second organic silane compound having the structure of SiX²₄, and (b) a second organic metal compound having the structure of MX²₃ or MX²₄; wherein each X² is independently a hydrolyzable substituent, and M is selected from Al, Zr, Ti, or combinations thereof; and the molar ratio of the second organic silane compound to the second organic metal compound is from 1:1 to 50:1.

12. A process of preparing the nanoparticles of claim 11, wherein the process comprises:
(i) providing a functionalized light emitting compound, wherein the functionalized light emitting compound has the structure of D-L-SiX₃, wherein D is a luminophore, L is a direct bond or an organic group, and X is a hydrolyzable substituent;
(ii) pre-hydrolyzing the functionalized light emitting compound;
(iii) adding a first precursor selected from a first organic silane compound having the structure of SiX¹₄, a first organic metal compound having the structure of MX¹₃ or MX¹₄, or mixtures thereof; wherein each X¹ is independently a hydrolyzable substituent, and M is selected from Al, Zr, Ti, or combinations thereof; and
(iv) adding a second precursor, wherein the second precursor comprises (a) a second organic silane compound having the structure of SiX²₄ and (b) a second organic metal compound having the structure of MX²₃ or MX²₄, wherein each X² is a hydrolyzable substituent, and M is selected from Al, Zr, Ti, or combinations thereof; thus to obtain the nanoparticles.

13. A light emitting composition comprising one or more than one types of the nanoparticles of claim 11, and an additional light emitting material that is different from the nanoparticles.

14. An electronic device comprising a layer of the nanoparticles of claim 11.

15. The electronic device of claim 14, wherein the layer further comprises a polymeric binder, fillers, additives, or mixtures thereof.

16. The electronic device of claim 14, wherein the electronic device is selected from a liquid crystal display device, an organic light-emitting device, and an inorganic light-emitting device.

17. The electronic device of claim 16, wherein the electronic device comprises a light emitting apparatus comprising the layer of the nanoparticles.
